(19) United States
(12) Patent Application Publication
(10) Pub. No.: US 2022/0120009 A1
(43) Pub. Date: Apr. 21, 2022

(54) KNOB STRUCTURE FOR WASHING MACHINE AND WASHING MACHINE

(71) Applicant: Whirlpool (China) Co., Ltd., Hefei (CN)

(72) Inventors: Yukai Huang, Hefei (CN); Hongqiang Wang, Hefei (CN); Fanmeng Hua, Hefei (CN); Yujin Mao, Hefei (CN)

(73) Assignee: Whirlpool (China) Co., Ltd., Hefei (CN)

(21) Appl. No.: 16/645,660

(22) PCT Filed: Jul. 3, 2019
(86) PCT No.: PCT/CN2019/094608

§ 371 Date: Dec. 30, 2021

(51) Int. Cl. D06F 34/30; D06F 34/32; G05G 1/10; G05G 1/02; G05G 25/00; H05K 1/18; H01H 19/14

(52) U.S. Cl. CPC D06F 34/30; D06F 34/32; G05G 1/10; G05G 1/02; H01H 2231/012; H05K 1/181; H01H 19/14; H05K 2201/10053; G05G 25/00

(57) ABSTRACT

The invention relates to a knob structure for a washing machine and a washing machine. The knob structure includes a knob component, a display component, a pressing component, and a PCBA board. The knob component includes a knob rotating seat, a fixed body and a knob decorative ring. The upper part of the knob rotating seat is provided with a receiving groove 1, the middle section is provided with a receiving groove 2, and the lower end is provided with a receiving groove 3; the inner peripheral wall of the receiving groove 2 is provided with a plurality of uneven grooves distributed uniformly. A metal conductive sheet A is installed at the bottom of the second receiving groove. A metal conductive sheet B, a metal conductive sheet C, and a metal conductive sheet D are mounted on the lower end of the fixed body. The display assembly includes a display base, a display module, and a glass lens. The pressing component includes a knob fixing bracket, a switch button and a rotary sound generator. The invention can solve the shortcomings in the prior art, has a rotating segment display function, and is simple and convenient to operate.

### TECHNICAL FIELD

The invention relates to the technical field of washing machines, in particular to a knob structure for a washing machine and a washing machine.

### BACKGROUND TECHNIQUE

At present, most of the control panels of washing machines are equipped with knobs. The knob and multiple buttons work together to set and switch program functions such as washing mode or washing time. The knobs of the existing washing machine are scattered and have no rotating segment display function, which is very inconvenient to operate and affects the user experience.

### SUMMARY OF THE INVENTION

The purpose of the present invention is to provide a knob structure and a washing machine for a washing machine. The knob structure and a washing machine for a washing machine can solve the problems existing in the prior art, have a rotating segment display function, and are simple and convenient to operate.

To achieve the above objective, the present invention adopts the following technical solutions:

A knob structure for a washing machine includes a knob component, a pressing component, and a display screen component, an incremental code wheel, and a PCBA board, wherein:

The rotating component can transmit the pressing force to the pressing component;

The display assembly is disposed in the rotating assembly and is electrically connected to the PCBA board. The display assembly is used to display various commands of the washing machine;

The incremental code wheel is arranged inside the rotating component and is electrically connected to the PCBA board. The incremental code wheel feedbacks different electrical signals to the PCBA board according to the change of the rotation angle of the rotating assembly, and the PCBA board processes the After the electrical signal, call the corresponding program and send the corresponding command to the display module;

The PCBA board is located under the pressing assembly, and the switch keys of the pressing assembly are electrically connected to the PCBA board. When the pressing assembly is lowered by an external force, the switch keys are turned on and the command on the display assembly is determined.

Further, the knob assembly includes a knob rotation base, a fixed body, and a knob decoration ring installed above the top of the knob rotation base; the upper end of the knob rotation base is provided with a receiving groove 1 and the middle portion is provided with a receiving groove 2 and a lower end; An accommodating groove 3 is provided; the inner peripheral wall of the accommodating groove 2 is provided with a plurality of uneven grooves which are evenly distributed.

Further, the display screen assembly includes a display base, a display module installed on the top of the display base and electrically connected to the PCBA board, and a glass lens pasted on the top of the display module; the upper end of the display base is placed on The lower end of the fixing body is located below the bottom of the second containing groove. The middle and upper ends of the fixing body pass through the second containing groove and are fixedly connected to the upper end of the display base. The knob decorative ring and the display assembly There is a gap between them.

Further, the pressing assembly includes a knob fixing bracket and a switch button; the knob fixing bracket includes a support plate, a support groove installed above the middle of the support plate, a support groove installed above the periphery of the support plate, and a support plate. Support slot three below; the switch button is installed in support slot one and is electrically connected to the PCBA board; the PCBA board is installed in support slot three; a rotating sound generator is also installed above the support board A base and a plurality of positioning posts; the positioning posts are located between the first support groove and the second support groove; the positioning post is sleeved with a return spring; the middle and lower ends of the knob turning base are embedded in the second support groove; The middle and lower ends of the display base pass through the accommodation grooves 2 and then extend into the support grooves 1 and are connected to the support grooves 1

Further, the knob structure further includes a waterproof component; the waterproof component includes a sealing ring A provided between the display base and the receiving groove 1 and a sealing ring provided between the receiving groove 1 and the supporting groove 2 B. A bottom cover installed at the bottom opening of the support groove three and a sealing ring C provided between the support groove three and the bottom cover.

Preferably, a claw and a guide groove are provided on the support groove.

Further, the knob structure further includes a rotary sound generator, and the rotary sound generator mounting base is arranged along the outer periphery of the support groove 1; the rotary sound generator includes a steel ball and a spring; and the rotary sound generator mounting base A mounting groove is provided on the upper side, and a cover plate is provided above the mounting groove, and the steel ball and the spring are sequentially installed in the mounting groove from the outside to the inside; the inner end of the spring is in contact with the outer peripheral wall of the support groove 1, and the outer The end is in contact with the steel ball; the outer end of the steel ball protrudes from the outside opening of the mounting groove to fit the concave-convex groove.

Further, the incremental encoder includes a metal conductive sheet A, a metal conductive sheet B, a metal conductive sheet C, and a metal conductive sheet D; a metal conductive sheet A is installed at the bottom of the accommodation slot 2; and the fixed body A metal conductive sheet B, a metal conductive sheet C, and a metal conductive sheet D are installed at the lower end; a plurality of contacts are uniformly arranged on the periphery of the upper end surface of the metal conductive sheet A according to a certain angle; the metal conductive sheets B, The pins of the metal conductive sheet C and the metal conductive sheet D are electrically connected to the PCBA board, respectively; the metal conductive sheet B, the metal conductive sheet C, and the metal conductive sheet D are all provided with antennae located outside the fixed body.

Further, a silicon switch is installed on the switch key; a switch bracket for fixing the key switch and the silicon switch is also installed on the support plate.

A washing machine includes a control panel, a touch display screen is provided on the front side of the control panel, and a touch display control system is provided on the back side; the control panel is further provided with a knob structure according to any one of claims 1 to 9; The touch display control system is electrically connected to the PCBA board.

The invention also relates to a washing machine, which includes a control panel. The front of the control panel is provided with a touch display screen and the back is provided with a touch display control system. The control panel is also provided with the knob structure described above. The touch display control system Electrically connected to the PCBA board.

It can be known from the above technical solution that the knob structure according to the present invention has a function of rotating and pressing. By rotating the knob structure, different programs can be selected, and the program content can be displayed on the touch display and display components in real time. You can determine the selected program, or you can directly touch the selected program through the touch screen or touch display control system to improve the space utilization of the control panel of the washing machine, and the operation is simple and convenient.

### BRIEF DESCRIPTION OF THE DRAWINGS

FIG.1 is a schematic diagram of an exploded structure of a knob structure in the present invention;

FIG. 2 is a longitudinal sectional view of a knob structure in the present invention;

FIG. 3 is a schematic diagram showing an assembly structure of a base and a knob fixing bracket in the present invention;

FIG. 4 is a schematic diagram of an assembly structure of a knob rotating base (not including a knob decorative ring), a display base and a fixed body according to the present invention; FIG. 4 is different from the cut-away position in FIG.

FIG. 5 is a schematic structural diagram of a fixing body in the present invention;

FIG. 6 is a schematic structural diagram of metal conductive sheets B, C, and D in the present invention;

FIG. 7 is an assembly schematic diagram of a knob turning base and a metal conductive sheet A in the present invention; FIG.

FIG. 8 is a schematic structural diagram of a knob rotating base in the present invention;

FIG. 9 is a longitudinal sectional view of a knob turning base in the present invention; FIG.

FIG. 10 is a schematic structural diagram of a knob fixing bracket in the present invention;

FIG. 11 is a longitudinal sectional view of a knob fixing bracket in the present invention;

FIG. 12 is a schematic structural diagram of a washing machine in the present invention;

FIG. 13 is an assembly schematic diagram of a control panel, a touch display control system, and a knob structure in the present invention;

FIG. 14 is an assembly schematic diagram of a touch display control system and a knob structure in the present invention.

among them:

1. Washing machine, 1-1, control panel, 1-2, touch display control system, 1-3, knob component, 1-4, touch display, 10, rotary component, 101, knob decorative ring, 102, knob rotation Block, 102-1, receiving slot one, 102-2, receiving slot two, 102-3 receiving slot three, 102-4, concave-convex slot, 103, metal conductive sheet A, 103-Z, metal conductive sheet A Contact Z, 104, fixed body, 104-A, metal conductive sheet A, 104-B, metal conductive sheet B, 104-C, metal conductive sheet C, 20, display assembly, 201, glass lens, 202, Display module, 203, display base, 30, pressing component, 301, knob fixing bracket, 301-1, support plate, 301-2, support slot 1, 301-3, support slot 2, 3014, support slot Three, 302, switch button, 303, silicone switch, 304, switch bracket, 305, return spring, 40, waterproof structure, 401, seal ring A, 402, seal ring B, 403, seal ring C, 404, bottom cover, 50. Rotating sound generator, 501, spring, 502, steel ball, 503, cover plate, 601, PCBA board, KZ, claw, DXC, guide groove, Y, positioning post.

### DETAILED DESCRIPTION

The invention is further described below with reference to the drawings:

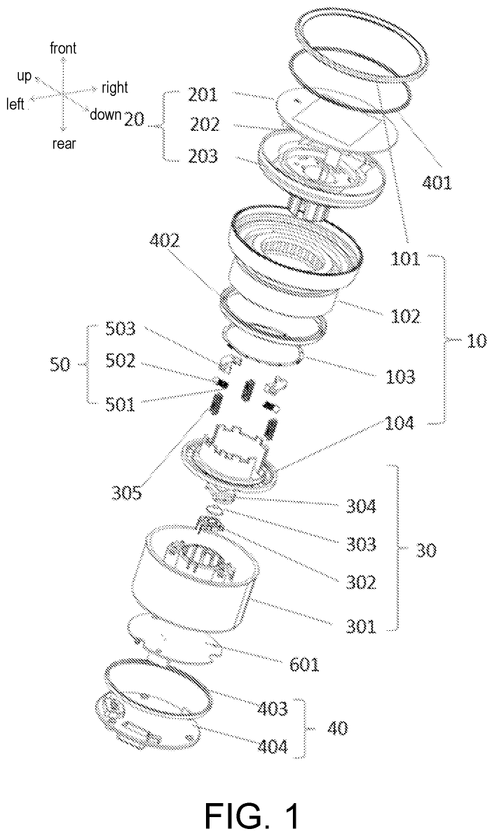

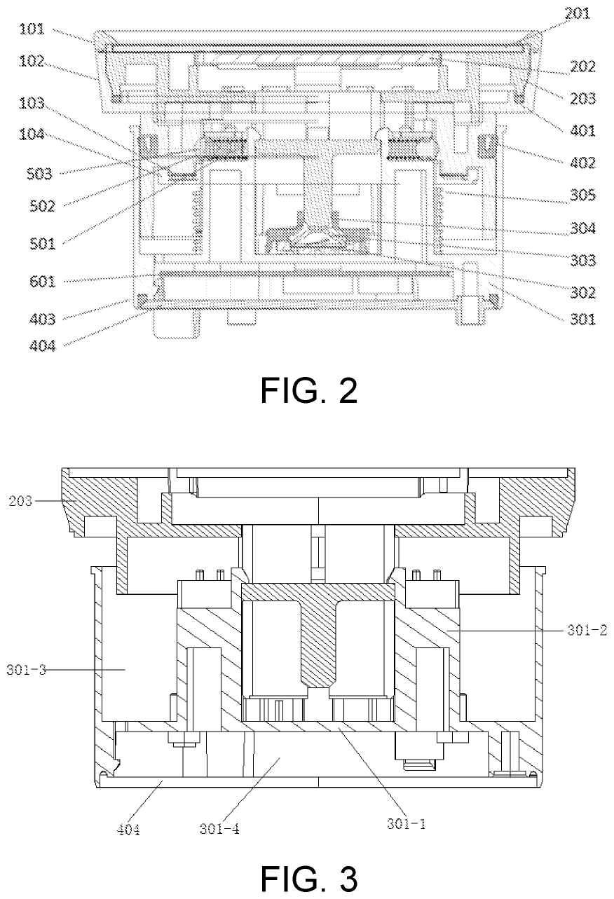

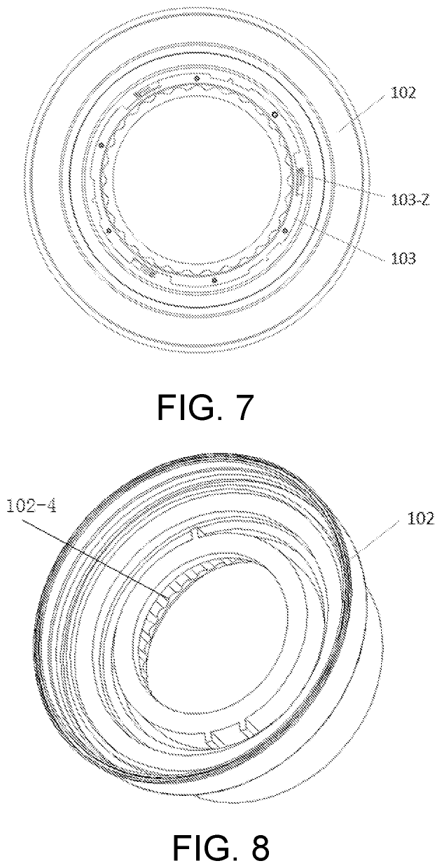

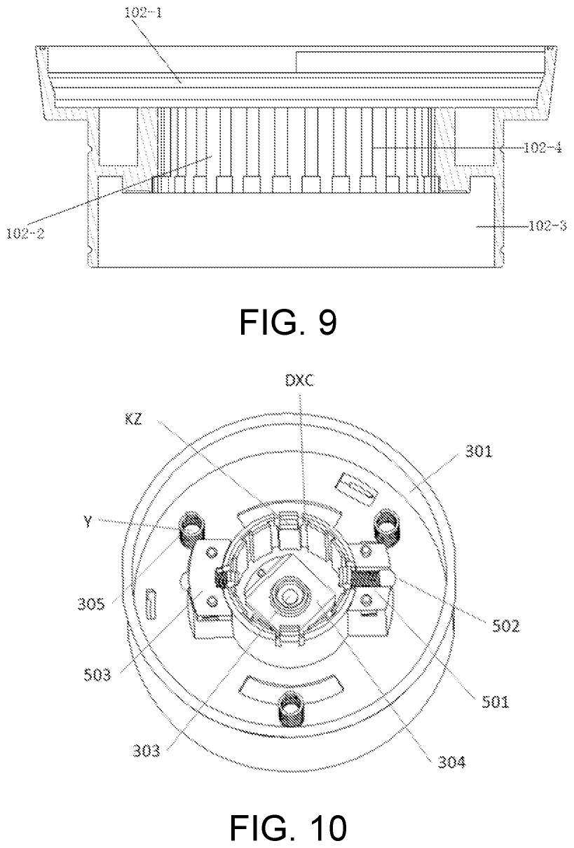

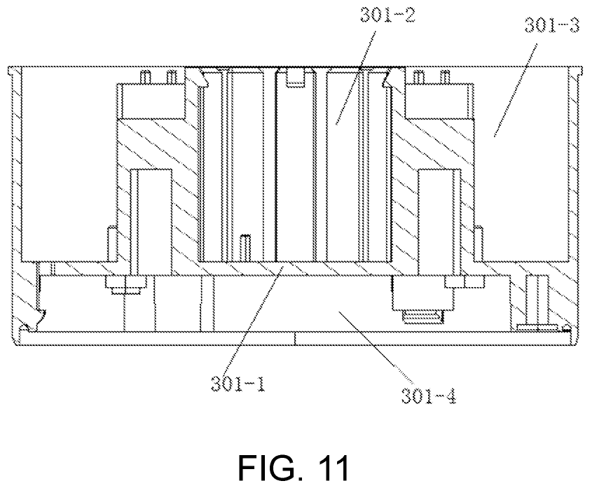

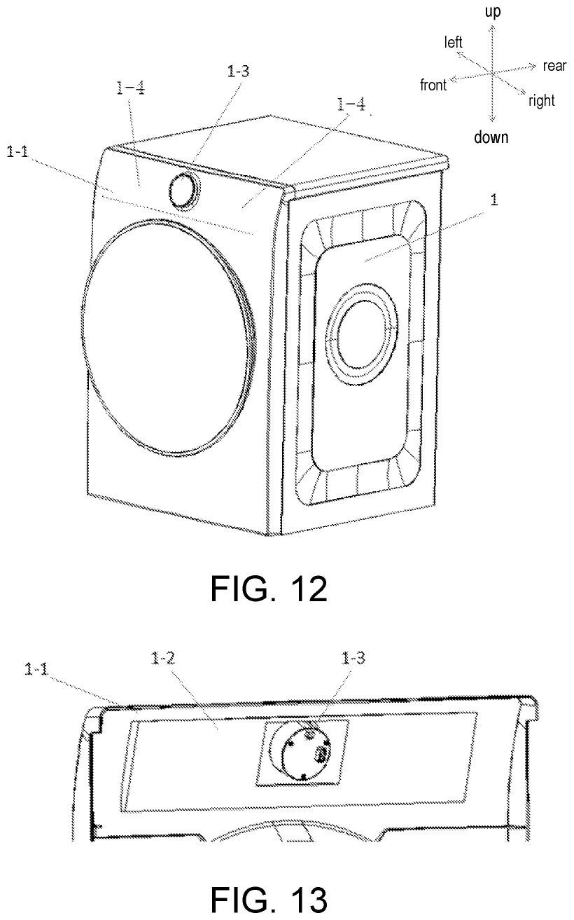

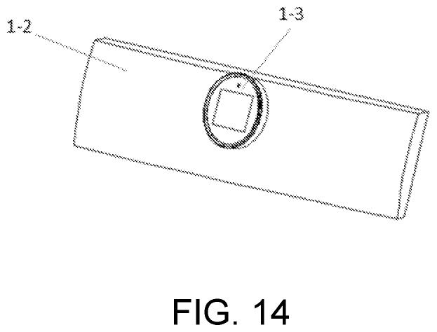

A knob structure for a washing machine as shown in FIG. 1 to FIG. 14 includes a knob assembly 10, a display assembly 20, a pressing assembly 30, and a PCBA board 601, wherein:

The rotating component 10 can transmit the pressing force to the pressing component 30, that is, the rotating component 10 can not only rotate on the washing machine, but also transmit the pressing force to the pressing component 30, so that the operator can simply By manipulating the rotating component 10 and controlling the compression of the pressing component 30, specifically, the rotating component 10 may be supported on the pressing component 30, and when the rotating component 10 is pressed down, the pressing component 30 is pushed to compress.

The display assembly 20 is disposed in the rotating assembly 10 and is electrically connected to the PCBA board 601. The display assembly 20 is used to display various commands of the washing machine. It can be seen that the operator can clearly know the order of the washing machine by rotating the assembly 10 It is no longer necessary to add another display component to the washing machine to assist the operator in operation. Of course, the display component 20 does not follow the rotation component 10 to rotate.

The incremental code wheel is disposed inside the rotating assembly 10 and is electrically connected to the PCBA board 601. The incremental code wheel feedbacks different electrical signals to the PCBA board 601 according to a change in the rotation angle of the rotating assembly 10. After processing the electrical signal, the PCBA board 601 sends a corresponding command to the display assembly 20. First, the incremental code wheel can measure the rotation angle and rotation direction of the rotary assembly 10, and then the PCBA board 601 can measure the rotation angle according to the rotation angle. Different, and after data processing, the corresponding program is called, and the corresponding command is displayed on the display screen assembly 20, and finally the operator enters different instructions by rotating the rotation assembly 10 at different angles.

The PCBA board 601 is located below the pressing assembly 30. The switch keys of the pressing assembly 30 are electrically connected to the PCBA board 601. When the pressing assembly 30 is lowered by an external force, the switch keys are turned on and the command on the display assembly 20 is determined. Because the operator can complete the pressing action of the pressing assembly 30 by operating the rotary assembly 10, when operating the washing machine, the operator completes the selection of the command only by rotating the rotary assembly 10, and presses the rotary assembly 10 (that is, the lower part) Press the pusher 30) to confirm execution of the command.

The knob assembly 10 includes a knob rotation base 102, a fixed body 104, and a knob decoration ring 101 installed above the top of the knob rotation base 102. The knob turning base 102 is provided with a receiving groove 1102-1 at the upper end, a receiving groove 2102-2 at the middle, and a receiving groove 3 102-3 at the lower end. The inner peripheral wall of the receiving groove two 102-2 is provided with a plurality of uneven grooves 102-4 which are evenly distributed. The plurality of concave and convex grooves 102-4 form a gear-like structure on the inner peripheral wall of the receiving groove 102-2. The concave-convex groove 102-4 is provided corresponding to the rotary sound generator 50. When the knob rotation base 102 and the rotary sound generator 50 fixed on the knob fixing bracket 301 are in relative motion, the steel ball 502 of the rotary sound generator 50 will roll along each of the concave and convex grooves 102-4, and move outward for a while, Move inward, and make contact with the inner wall of the uneven receiving groove 2 to make a clicking sound. For example, the outer end of the steel ball 502 first enters the recess of the concave-convex groove 102-4. At this time, the spring 501 is in the original length or compressed state, and then enters the convex portion of the concave-convex groove 102-4. The convex portion gives the steel ball 502 A force directed at the spring 501 causes the steel ball 502 and the spring 501 to be squeezed. When the steel ball 502 enters the next recess of the concave-convex groove 102-4, the steel ball 502 will return to the direction of the spring 501. Lateral movement. The knob decorative ring 101 and the knob rotation base 102 are fixedly connected together, and the two are rotated together with the center line of the knob rotation base 102 as a rotation axis. The fixed body 104 cannot be rotated together with the knob rotation base 102.

A metal conductive sheet A103 is installed at the bottom of the second receiving groove 102-2. A metal conductive sheet B104-B, a metal conductive sheet C104-C, and a metal conductive sheet D104-D, a metal conductive sheet B104-B, a metal conductive sheet C104-C, and a metal conductive sheet D104-D are installed at the lower end of the fixed body 104. It is injection-molded with the fixing body 104. The metal conductive sheet A103 is provided with a plurality of contacts Z, and the plurality of contacts Z are distributed at a certain angle on the metal conductive sheet A103. The pins of the metal conductive sheet B104-B, the metal conductive sheet C104-C, and the metal conductive sheet D104-D are all electrically connected to the PCBA board 601. The metal conductive sheet B104-B, the metal conductive sheet C104-C, and the metal conductive sheet D104-D are all provided with antennae 104-1 on the outside of the fixed body, and the antennae of each metal conductive sheet are arranged according to a certain rule. The metal conductive sheet A can be rotated together with the knob turning seat. When rotating, the contact point Z on the metal conductive sheet A and the metal conductive sheet B, the metal conductive sheet C, and the metal conductive sheet D are exposed on the outside of the fixed body correspondingly to form an antenna. The incremental encoder function transmits the rotation signal to the PCBA board 601, and then different programs can be selected.

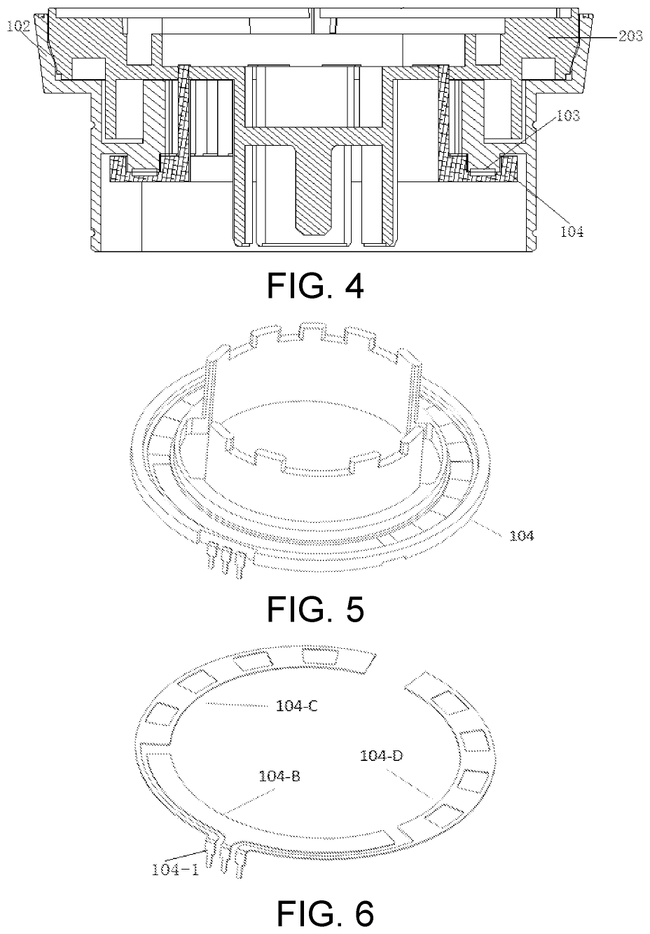

The display module 20 includes a display base 203, a display module 202 installed on the top of the display base 203 and electrically connected to the PCBA board 601, and a glass lens 201 attached to the top of the display module 202 through optical glue. As shown in FIG. 4, the upper end of the display base 203 is placed in the receiving slot 1 102-1; the lower end of the fixing body 104 is located below the bottom of the receiving slot 2 102-2, and the upper and middle ends of the fixing body 104 After passing through the accommodating slot two 102-2, it is fixedly connected to the upper end of the display base 203.

The pressing assembly 30 includes a knob fixing bracket 301, a switch button 302, and a rotary sound generator 50. The knob fixing bracket 301 includes a support plate 301-1 and a support groove 301-2 installed above the middle of the support plate 301-1. A support slot 301-3 installed above the outer periphery of the support plate 301-1 and a support slot three 301-4 installed below the support plate 301-1; the switch button 302 is installed in the support slot 301-2, and It is electrically connected with the PCBA board 601; the PCBA board 601 is installed in the supporting slot III 301-4; a rotating sound generator mounting base and a plurality of positioning posts Y are installed above the supporting board 301-1; the rotation The sound generator mounting seat is provided along the outer periphery of the support slot 1-301-2; the positioning post Y is located between the support slot 1 301-2 and the support slot 2 301-3; the positioning post Y is provided with a return spring 305 The rotating sound generator 50 includes a steel ball 502 and a spring 501;

1-10. (canceled)

11. A knob structure for a washing machine, comprising:
a rotating component;
a pressing component;
a display component;
an incremental code wheel; and
a PCBA board, wherein:
the rotating component can transmit a pressing force to the pressing component;
the display component is disposed in the rotating component and is electrically connected to the PCBA board;
the display component is used to display various commands of the washing machine;
the incremental code wheel is arranged inside the rotating component and is electrically connected to the PCBA board;
the incremental code wheel feeds back different electrical signals to the PCBA board according to a change of a rotation angle of the rotating component, and the PCBA board processes the electrical signal, calls a corresponding command and send the corresponding command to the display module;
the PCBA board is located under the pressing component, and switch keys of the pressing assembly are electrically connected to the PCBA board; and
when the pressing assembly is lowered by an external force, the switch keys are turned on and the command on the display assembly is determined.

12. The knob structure for a washing machine according to claim 11, wherein the rotating component comprises:
a knob rotation base;
a fixed body; and
a knob decoration ring installed above a top of the knob rotation base, wherein an upper end, a middle section and a lower end are each provided with a receiving slot, wherein an inner peripheral wall of the receiving slot of the middle section is provided with a plurality of uneven grooves that are evenly distributed.

13. The knob structure for a washing machine according to claim 12, wherein the display component comprises:
a display base;
a display module installed on a top of the display base and electrically connected to the PCBA board, and pasted on a glass lens on a top of the display module, wherein an upper end of the display base is placed in one of the receiving slots and a lower end of the fixed body is located below the bottom of the receiving slot of the middle section, and wherein the middle and upper ends of the fixed body pass through the second receiving slot and the upper end of the display base is fixedly connected, and a gap is provided between the knob decoration ring and the display component.

14. The knob structure for a washing machine according to claim 13, wherein the pressing component comprises:
a knob fixing bracket;
a switch button, wherein the knob fixing bracket comprises a supporting plate and a first support groove installed above the middle of the supporting plate, and wherein a second support groove is installed above the outer periphery of the support plate and a third support groove is installed below the support plate, wherein the switch button is installed in the first support groove and is electrically connected to the PCBA board, the PCBA board is installed in the third support groove;
a rotating sound generator mounting base and a plurality of positioning columns that are also installed above the support plate, wherein the positioning columns are located between the first and second support grooves, and wherein a positioning column is provided with a return spring and the lower end and middle section of the knob turning base are embedded and arranged in the second support groove and the lower end and middle section of the display base pass through the second support groove and extend into the first supporting groove and are connected to the first supporting groove.

15. The knob structure for a washing machine according to claim 14, further comprising:
a waterproof component that includes a sealing ring A provided between the display base and the first support groove, a sealing ring B between the first support groove and the second support groove, a bottom cover installed at an opening at the bottom of the third support groove, and a sealing ring C provided between the third supporting groove and the bottom cover.

16. The knob structure for a washing machine according to claim 15, wherein one of the support grooves is provided with a claw and a guide groove.

17. The knob structure for a washing machine according to claim 16, further comprising:
a rotary sound generator wherein the rotating sound generator mounting seat is arranged along the outer periphery of the first support groove, wherein the rotary sound generator includes a steel ball and a spring, and a mounting groove is provided on the rotating sound generator mounting base, and a cover plate is provided above the mounting groove, and the steel ball and the spring are sequentially installed in the mounting groove from the outside to the inside, wherein an inner end of the spring is in contact with the outer peripheral wall of the first support groove and an outer end of the spring is in contact with the steel ball, wherein the outer end of the steel ball is extended from the outer opening of the mounting groove to fit the concave-convex groove.

18. The knob structure for a washing machine according to claim 17, wherein the incremental code wheel comprises:
a metal conductive sheet A;
a metal conductive sheet B;
a metal conductive sheet C; and
a metal conductive sheet D, wherein the metal conductive sheet A is installed at the bottom of the second support groove, wherein the metal conductive sheet B, the metal conductive sheet C, and the metal conductive sheet D are installed at the lower end of the fixed body;
a plurality of contacts that are uniformly arranged at the corners, wherein pins of the metal conductive sheet B, the metal conductive sheet C, and the metal conductive sheet D are electrically connected to the PCBA board, respectively, and wherein each of the metal conductive sheet B, the metal conductive sheet C, and the metal conductive sheet D are provided with antennas located outside the fixed body.

19. The knob structure for a washing machine according to claim 18, wherein a silicon switch is installed on the switch button and a switch bracket for fixing the key switch and the silicon switch is also installed on the support plate.

20. A washing machine comprising a control panel, characterized in that: a touch display screen is provided on the front side of the control panel, and a touch display control system is provided on the back side; and wherein the knob structure of claim 11 is provided on the control panel, wherein the touch display control system is electrically connected to the PCBA board.
